(19) United States
(12) Patent Application Publication
(10) Pub. No.: US 2013/0294015 A1
(43) Pub. Date: Nov. 7, 2013

(54) SELF-HEALING ACTIVE ARMOR MEMBRANE

(71) Applicant: Patrick DiStefano, Camarillo, CA (US)

(72) Inventor: Patrick DiStefano, Camarillo, CA (US)

(21) Appl. No.: 13/461,038

(22) Filed: May 1, 2012

(51) Int. Cl. H05K 5/03

(52) U.S. Cl. 361/679.01

(57) ABSTRACT

The invention generally relates to protective covers used on electronic appliances or devices. It more particularly relates to a protective cover that enhances the user experience of devices such as smartphones, tablets and the like. In one aspect the invention includes adhesive backing for attachment to a surface, a printable substrate and a clear magnifying dome covering the substrate, combined into a unit that when adhered to a surface provides a clear bright decorative protective covering. The protective covering is preferably made from tough self-healing materials, and the flat substrate is suitable as a base for either printed images, preferably customizable, and/or small decorative objects such as jewels, small insects or the like.

### RELATED APPLICATIONS

Not Applicable

### FEDERALLY SPONSORED RESEARCH

Not Applicable

### SEQUENCE LISTING

Not Applicable

### FIELD OF THE INVENTION

The invention generally relates to protective covers used on electronic appliance or devices. It more particularly relates to protective covers that enhance the user experience of devices such as smartphones, tablets and the like.

### BACKGROUND OF THE INVENTION

Modern personal computing appliances or devices, such as smartphones and tablets, are generally expensive and relatively delicate. A variety of after-market protective coverings are available for the devices. The coverings, however, are of limited variety. There is accordingly a need for novel coverings that satisfy consumer demand.

### BRIEF SUMMARY OF THE INVENTION

In one aspect, the invention is a raised protective cover for a surface such as the back of a smartphone, including a printable media substrate, sized to substantially fill the area of the surface, an adhesive, and a clear, magnifying dome over the media surface. The substrate, backing, and magnifying dome are formed together into a unitary object, attachable to the surface with the adhesive, to form a raised protective cover.

In some embodiments, the media substrate is vinyl and/or the clear magnifying dome is made from a mixture of Isocyanate and Polyol. The dome may be optionally treated with acetone after curing to provide a sticky aspect to the surface

In preferred embodiments, the height of the protective covering from adhesive to the top of the dome is greater than 0.1 inches.

In another embodiment, the substrate and dome covering are substantially rectangular in outline. In a particular version, the dimensions of the covering are selected to cover the back (and/or front) of a specific appliance and may include cutouts for appliance components such as camera lenses.

In various detailed embodiments, the media substrate is printed with an image and/or a decorative object is enclosed within the dome. At least one of the substrate or the cover may contain glow-in-the-dark material. In a particular embodiment the protective covering may contain a light source (or sources), preferably an LED, and a power supply, preferably including a solar cell. The light source is preferably controlled by a controller. In one version the protective covering is applied to the back (and/or front) of a personal appliance or device, and the light source controller includes a wireless interface which may connect to a wireless interface on the personal device. In conjunction with an application running on the personal device, the light source is caused to flash in time with music playing on the device. The light source, power supply and controller can take several alternate configurations or combinations of configurations, including, conventional battery—possibly removable—, motion activated, and direct activation.

### BRIEF DESCRIPTION OF THE DRAWINGS

The invention will be better understood by referring to the following figures.

FIG. 1 shows views of an exemplary device with and without the invention installed.

FIG. 2 shows several elements of the invention in cross-section.

FIG. 3 shows alternative versions of the invention.

FIG. 4 shows a preferred embodiment of the invention.

FIG. 5 shows the invention with an image on the substrate.

FIG. 6 shows the invention with a decorative object on the substrate.

FIG. 7 shows the invention with an integrated light source, controller and wireless interface.

FIG. 8 shows the invention with additional user-applied stick-on images.

### DETAILED DESCRIPTION OF THE INVENTION

The invention generally relates to protective coverings used on electronic devices. It more particularly relates to protective coverings that enhance the user experience of devices such as smartphones, tablets and the like.

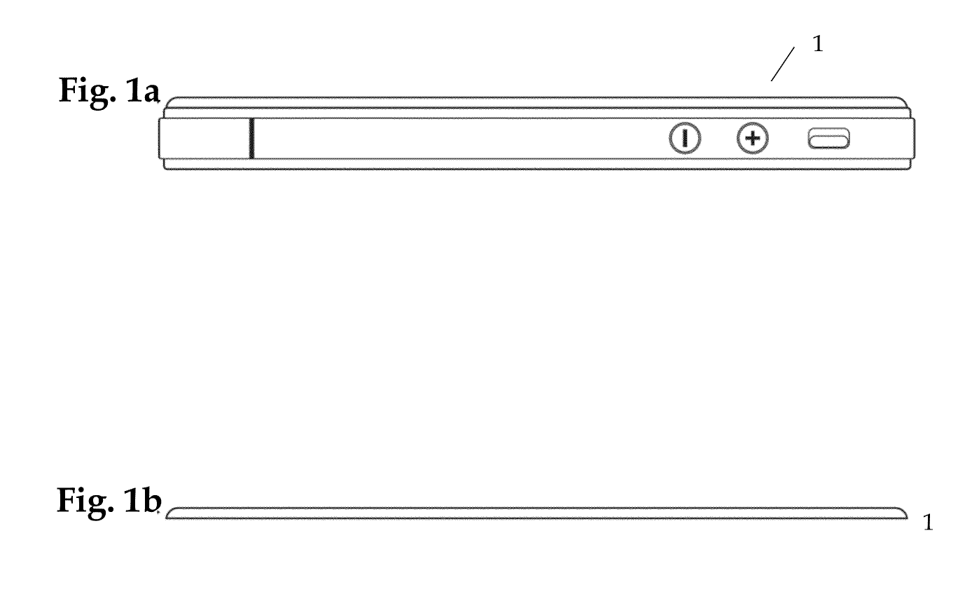

In one aspect, the invention is a raised domelike protective covering that can be attached by a user to surface such as the front and/or back of a smartphone or tablet. FIGS. 1a and 1b respectively show an exemplary device with and without the installed invention 1.

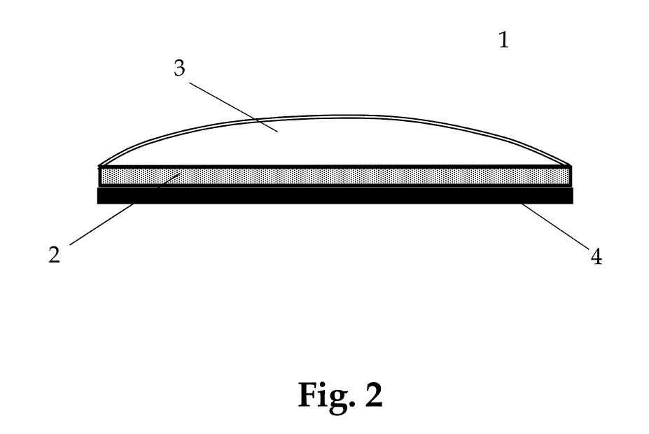

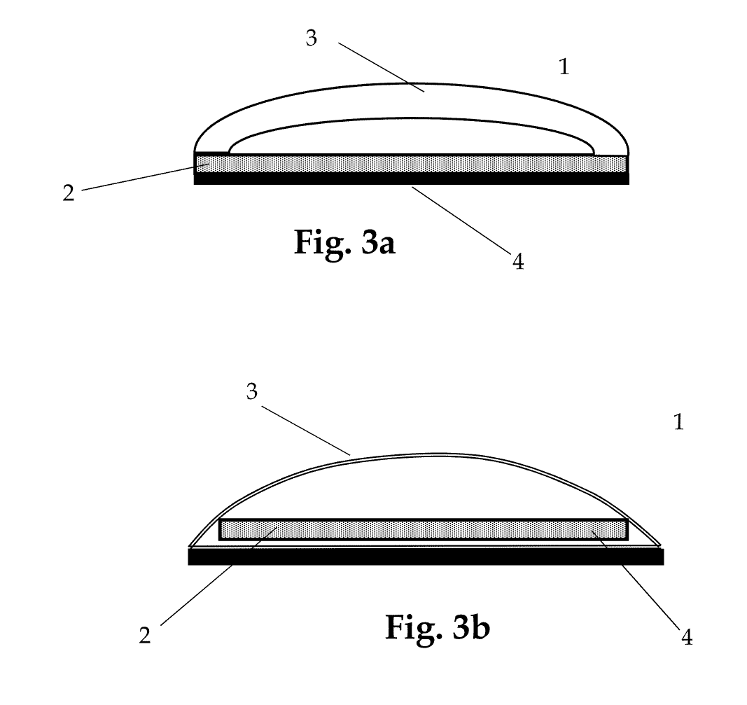

The covering is structurally unique. Referring to FIG. 2, covering 1 is an assembly containing at least three elements. First, a substrate 2, comprising a printable media forms the base of the protective covering. Preferably, an adhesive backing 4 is formed on the bottom of substrate 2. Suitable implementations of the adhesive backing are well known in the art. Formed onto the substrate is a clear raised dome cover 3, chosen for both suitable material properties and to provide magnification of the substrate. The three elements are formed together into a membrane sticker, which can be adhered to a surface providing a highly protective covering. The magnifying dome causes the substrate surface to be bright and clear, allowing for very finely detailed, colorful images or structures to be viewed with high clarity. The preferred covering is shown in FIG. 2 with the dome material 3 completely filling the volume above the substrate 2. However, alternative implementations will suggest themselves to one skilled in the art. For instance, as shown in FIG. 3a dome 3 may enclose some open space as opposed to filling the volume completely. Alternatively, as shown in FIG. 3b, the substrate 2 may be potted within the dome material 3 and the adhesive 4 may be applied to the dome material 3.

Suitable materials for the printable media substrate include vinyl, which is strong and resilient even in thin sheet form and easily colored to suit a particular style or visual appearance.

In an embodiment, the chemical compositions forming the dome comprise an isocyanate, Chem Dec 808 Isocyanate, and a polyol, Chem Dec 808 Polyol. The compositions are substantially and evenly mixed by a doming machine to create the dome compound. The material is clear, does not yellow, is tough and has self-healing properties; it exhibits both viscous and elastic characteristics. When pressure or penetrating forces are applied to the dome causing deformation or tensile stress, the material can quickly return to its original shape once the stress is removed. Optionally, the dome surface may be treated with acetone after cutting. This has the effect of making the surface slightly sticky, and for some devices such as many smartphones, depending on type of surface desired, may allow for the device to be removably fixed to a horizontal, angled, or vertical surface. This feature may in some cases allow for handsfree operation of the device. Nonlimiting examples of such handsfree operation include sticking the device to a cold metal surface, mirror or window to talk on the telephone, watch videos, or take pictures and/or videos (e.g., use as an image stabilizer).

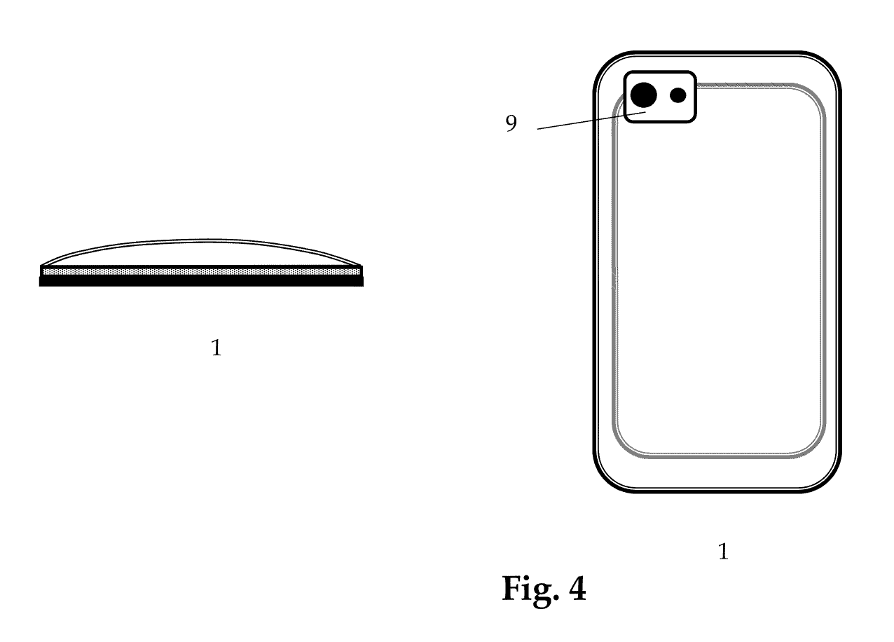

The membrane protective covering can be constructed and applied to fit a wide range of applications. For instance, the protective covering 1 may be rectangular as shown in FIG. 4 and sized to cover the back and/or front of a specific personal appliance. Covering 1 may optionally include cutouts 9 to allow access to device components such as camera lenses, flashes, microphones and the like. The height range of the membrane covering—i.e., from the bottom of the substrate to the top of the dome—is typically less than 0.1″. Nonlimiting examples of height ranges include: 0.01″ to 0.095″ and 0.05″ to 0.090″.

Although most smartphones, tablets, handheld games and such personal appliances are rectangular, the protective covering may be made in other shapes, such as circles, stars, polygons and the like, as well as a in a variety of sizes.

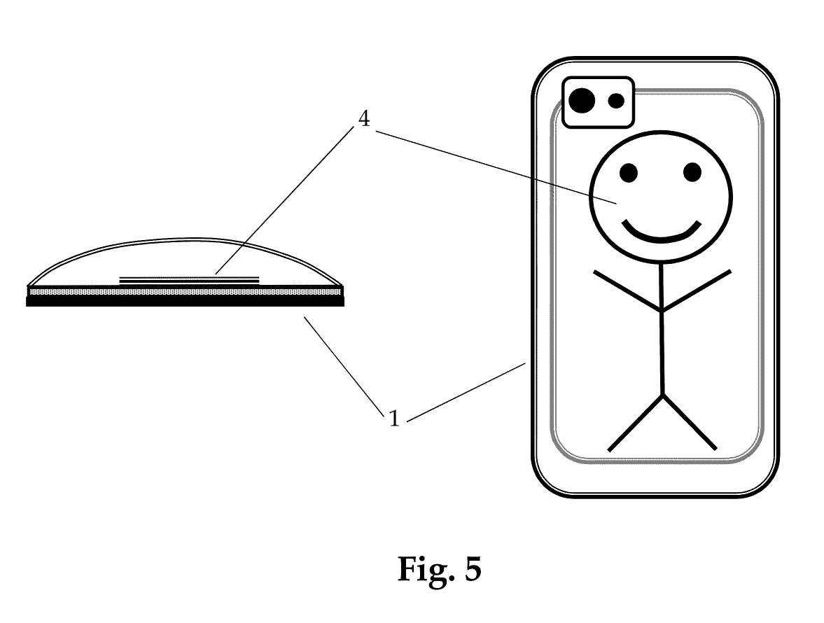

The membrane protective covering typically includes at least one decorative element. As shown in FIG. 5, an image 4 may be printed on the substrate. With a clear dome of the type described above, detailed images such as faces are clearly resolvable, even for high density images.

The coverings can be made with user specified images. An image can be uploaded using an online ordering process, and it can be applied to the coverings. Manufacturing membrane coverings with specified images can be performed in small numbers (10 or even less) without appreciably increasing the cost of manufacturing compared to coverings with stock images.

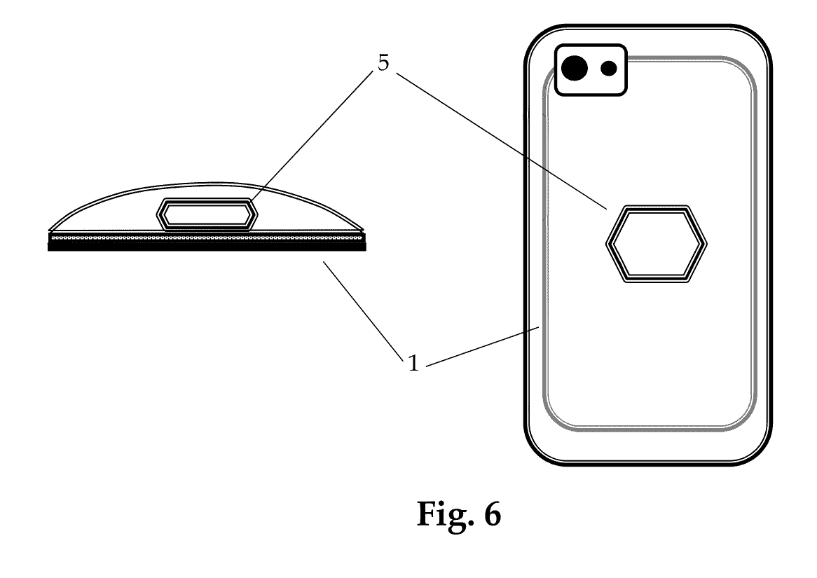

As shown in FIG. 6, alternatively or in conjunction with a printed image, a small object (or objects), (stone, insect, etc.) may be placed on the substrate and anchored in place by adhesive, the potting effect of the dome or some combination thereof. The membrane covering structure may optionally be impregnated with a glow in the dark substance of a kind known in the art.

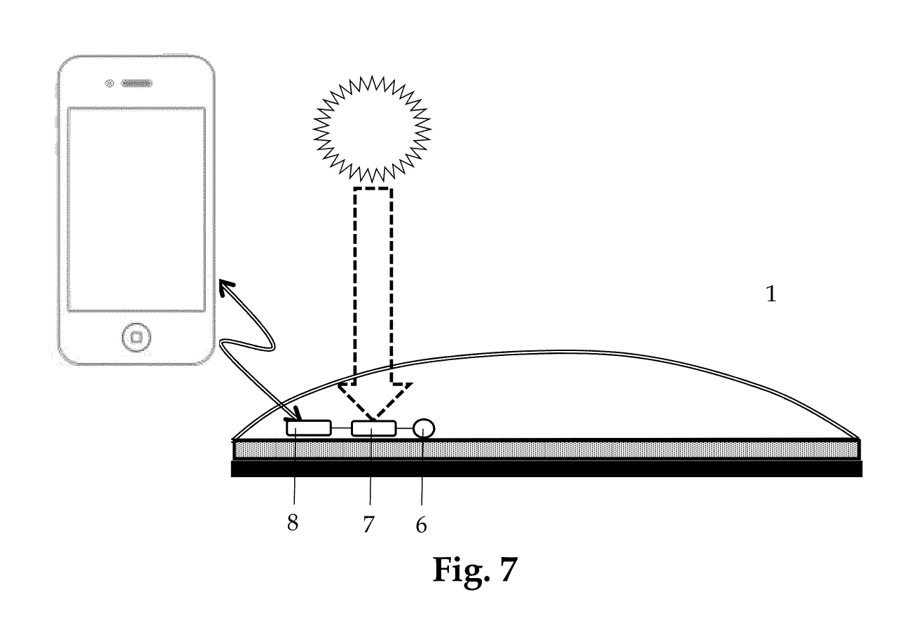

The membrane covering 1 as shown in FIG. 7 may also contain an integrated light source 6 (or sources), preferably an LED, and power supply 7. Preferably the power supply 7 for light source 6 includes a solar cell. A controller 8 to actuate the light source 6 also preferably is included. Although the controller 8 operation may be simple such as pressure sensitive, a more complicated version is possible. Controller 8 may include a wireless interface such as Bluetooth, compatible with the Bluetooth interface commonly found on devices such as smartphones. The wireless light source controller interface could connect with the device interface and, in conjunction with an application running on the device, cause the light source to flash in time with music played on the device. Variants such as multiple colored light sources with different colors flashing at different times would also be possible. The controller may also be motion activated or light sensitive, or some combination of external signal and direct activation. The lighted membrane covering can serve as an emergency light source to provide visibility for a user in dark conditions such as an unlit road at night. The membrane may also be programmed through the application to light-up for incoming calls, email and text notifications.

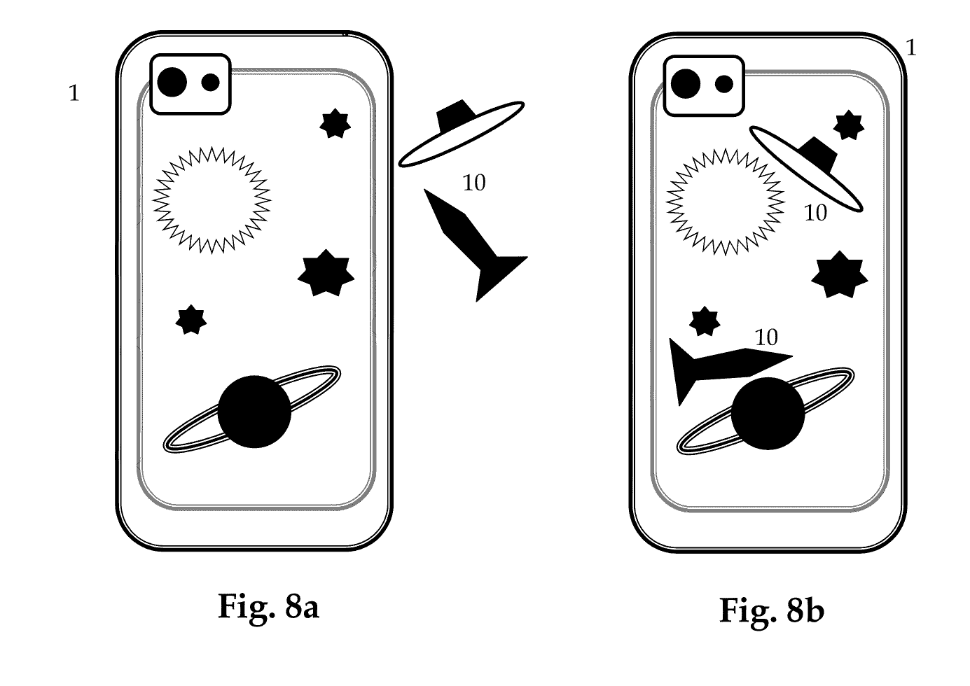

Further decorative options are possible with the unique protective covering and its method of manufacture. As shown in FIG. 8, covering 1 may be blank, or with an image, and stick-on elements 10 may be user selected. The stick-on elements may be placed on the cover 1 such that they, either alone or in conjunction with an image on the media substrate, form user changeable images. Variations such as clothing items, which may be overlaid over a figure, or game pieces overlaid over a gameboard, are exemplary variants. These stick-on elements may be adhesively or magnetically attached. Also the unique construction of the covering allows for painting of highly unique designs by an artist on either fully or partially completed membrane coverings, which may be protected with another dome layer.

The foregoing description of the embodiments of the present invention have shown, described and pointed out the fundamental novel features of the invention. It will be understood that various omissions, substitutions, and changes in the form of the detail of the systems and methods as illustrated, as well as the uses thereof, may be made by those skilled in the art, without departing from the spirit of the invention. Consequently, the scope of the invention should not be limited to the foregoing discussions, but should be defined by appended claims.

1. A raised protective cover for a surface such as the back (and/or front) of a smartphone or other personal appliance, comprising:
a printable media substrate, sized to substantially cover the area of the surface,
an adhesive backing for the media substrate; and,
a clear, magnifying dome over the media surface; wherein the substrate, backing, and magnifying dome are formed together into a unitary object, attachable to the surface, to form a raised protective cover.

2. The protective cover of claim 1 wherein the media substrate is vinyl.

3. The protective cover of claim 1 wherein the clear magnifying dome is made from a mixture of Isocyanate and Polyol, and is optionally treated with acetone after curing.

4. The protective cover of claim 1 wherein the height of the cover from adhesive to the top of the dome is greater than 0.1 inches.

5. The protective cover of claim 1 wherein the substrate and dome covering are substantially rectangular in outline, sized to cover the back (and/or front) of a specific appliance and optionally comprise cutouts for appliance components including camera lenses.

6. The protective cover of claim 1 wherein the media substrate is printed with an image.

7. The protective cover of claim 1 wherein a decorative object is adhered to the substrate.

8. The protective cover of claim 1 wherein the dome material is chosen to have at least one of;
self-healing properties resistant to damage, or
a semi-sticky surface.

9. The protective cover of claim 1 further comprising removable stick-on objects that form user-defined decorative patterns by at least one of by themselves or as an overlay for an image on the media substrate.

10. The protective cover of claim 1 further comprising at least one light source and a power supply for the light source.

11. The protective cover of claim 10 wherein the light source is an LED.

12. The protective cover of claim 10 wherein the power supply comprises at least one of a solar cell, conventional battery or removable battery.

13. The protective cover of claim 10 further comprising a controller for the light source.

14. The protective cover of claim 13 wherein the controller comprises a wireless interface.

15. The protective cover of claim 14 wherein the protective cover is used as a backside (and/or frontside) protective cover on a computing device and the wireless interface is compatible with a wireless interface on the device.

16. The protective cover of claim 15 wherein the covering wireless interface connects to the device interface and in conjunction with an application running on the device causes the light source to flash in time with music playing on the device.

17. The protective cover of claim 13 wherein the controller is at least one of motion activated, direct activated, or light sensitive.
